(19) United States
(12) Patent Application Publication
(10) Pub. No.: US 2026/0333632 A1
(43) Pub. Date: Oct. 22, 2026

(54) SERVER COOLING SYSTEM AND DEGASSING APPARATUS AND OPERATING FLUID DISTRIBUTION UNIT THEREOF

(71) Applicant: Wiwynn Corporation, New Taipei City (TW)

(72) Inventors: Yu-Zhou LIN, New Taipei City (TW); Yi CHENG, New Taipei City (TW); Tsung-Han LI, New Taipei City (TW); Tsung-Yi CHEN, New Taipei City (TW)

(21) Appl. No.: 19/565,765

(22) Filed: Mar. 13, 2026

(30) Foreign Application Priority Data
Apr. 22, 2025 (TW) 114115242

(51) Int. Cl. H05K 7/20; B01D 19/00

(52) U.S. Cl. CPC H05K 7/20327; B01D 19/0042; B01D 19/0068; B01D 19/0094; H05K 7/203; H05K 7/20318; H05K 7/20809

(57) ABSTRACT

A server cooling system and a degassing apparatus and an operating fluid distribution unit thereof are provided. The server cooling system includes a liquid cooling apparatus and a degassing apparatus. The degassing apparatus includes a heater, a radiator, and a liquid-gas separator. The heater is in communication with the radiator. The liquid-gas separator is in communication with the radiator and the liquid cooling apparatus. In addition, an operating fluid distribution unit includes a heat exchanger, an operating fluid reservoir in communication with the heat exchanger, a fluid propeller in communication with the operating fluid reservoir, a heater in communication with the fluid propeller, a radiator in communication with the heater, a liquid-gas separator in communication with the radiator, and a filter in communication with the liquid-gas separator.

### CROSS-REFERENCE TO RELATED APPLICATION

This non-provisional application claims priority under 35 U.S.C. § 119(a) to Patent Application No. 114115242 filed in Taiwan, R.O.C. on Apr. 22, 2025, the entire contents of which are hereby incorporated by reference.

### BACKGROUND

### Technical Field

The present invention relates to a server cooling system and a degassing apparatus and an operating fluid distribution unit thereof.

### Related Art

Since a server generates a large amount of heat during operation, the server is usually configured with a cooling apparatus system to take away the heat. A current cooling apparatus may be a rack-mounted or immersion cooling apparatus. The rack-mounted cooling apparatus generally includes a liquid cooling module and a server respectively configured in separate racks. Alternatively, the liquid cooling module may be configured on a rear door of a server rack, or the liquid cooling module and the server may be configured in the same rack. In addition, the immersion cooling apparatus may have different structures based on single-phase or two-phase coolants. For example, an immersion cooling apparatus may include an immersion tank, a water chiller unit, a cooling water pipeline, and a cooling water monitoring host.

### SUMMARY

According to the inventor's knowledge, a coolant in a cooling circulation apparatus is usually filled into a chassis or an immersion tank in a room temperature (such as 25 °C) before a server is started to operate. However, when the coolant absorbs heat from the server and vaporizes, the vaporized gas includes not only the gaseous coolant, but also the gas originally dissolved in the liquid coolant. A pressure in the chassis or the immersion tank increases correspondingly, resulting in that an air pressure in the chassis or the immersion tank cannot be stably maintained, which may cause fluid leakage. In addition, the vaporized gas may also cause a problem of hardware damage.

Embodiments of the present invention provide a server cooling system and a degassing apparatus and an operating fluid distribution unit thereof.

According to some embodiments, the server cooling system includes a liquid cooling apparatus and a degassing apparatus. The degassing apparatus includes a heater, a radiator, and a liquid-gas separator. The radiator is in communication with the heater. The liquid-gas separator is in communication with the radiator and the liquid cooling apparatus.

According to some embodiments, the operating fluid distribution unit includes a heat exchanger, an operating fluid reservoir, a fluid propeller, a heater, a radiator, a liquid-gas separator, and a filter. The operating fluid reservoir is in communication with the heat exchanger. The fluid propeller is in communication with the operating fluid reservoir. The heater is in communication with the fluid propeller. The radiator is in communication with the heater. The liquid-gas separator is in communication with the radiator. The filter is in communication with the liquid-gas separator.

According to some embodiments, the degassing apparatus includes a heater, a radiator, and a liquid-gas separator. The heater is configured to heat an operating fluid to output a heated fluid. The heated fluid has a first temperature, and the first temperature is higher than an operating temperature of the operating fluid. The radiator is configured to condense the heated fluid to output a heat dissipation fluid. The heat dissipation fluid has a second temperature, and the second temperature is lower than the operating temperature. The liquid-gas separator is configured to perform liquid-gas separation on the heat dissipation fluid to respectively output a degassed fluid and a gas.

Based on the above, according to some embodiments, the operating fluid is first degassed before being filled into the liquid cooling apparatus, so that the air pressure in the chassis or an immersion tank may be maintained, thereby reducing a degree of fluid leakage. According to some embodiments, the risk of hardware damage due to gas expansion caused by heat exchange may also be reduced.

### BRIEF DESCRIPTION OF THE DRAWINGS

FIG. 1 illustrates a schematic diagram (I) of a server cooling system according to some embodiments, with arrows indicating a flow direction of an operating fluid;

FIG. 2 illustrates a schematic cross-sectional view of a liquid-gas separator according to some embodiments, in which a spiral liquid guide plate and a portion of a gas guide pipe member are not sectioned;

FIG. 3 illustrates a schematic diagram (II) of a server cooling system according to some embodiments, with arrows indicating a flow direction of an operating fluid;

FIG. 4 illustrates a schematic diagram (III) of a server cooling system according to some embodiments, showing that a first operation unit, a second operation unit, and a third operation unit are configured in a same server rack;

FIG. 5 illustrates a schematic diagram (IV) of a server cooling system according to some embodiments, showing a connection relationship between a first operation unit and a degassing apparatus, with arrows indicating a flow direction of an operating fluid;

FIG. 6 illustrates a schematic diagram (V) of a server cooling system according to some embodiments, showing a connection relationship between a first operation unit, a second operation unit, and a third operation unit, with arrows indicating a flow direction of an operating fluid;

FIG. 7A illustrates a schematic structural diagram of a first operation unit according to some embodiments, showing that a liquid cooling apparatus further includes a cold plate module, and a plurality of to-be-cooled elements are configured in a chassis;

FIG. 7B illustrates a partial enlarged view of an area D marked in FIG. 7A and viewed from the bottom to top of a perspective of FIG. 7A in the area D, showing a connection relationship between a to-be-cooled element, a cold plate, an intake manifold branch, and an exit manifold branch;

FIG. 8A illustrates a schematic top view of a first operation unit according to some other embodiments, showing that a chassis of the first operation unit is a sealed chassis to accommodate an operating fluid, a boiler, and a to-be-cooled element; and

FIG. 8B illustrates a partial enlarged view of an area D marked in FIG. 8A and viewed from the bottom to top of a perspective of FIG. 8A in the area D, showing a to-be-cooled element and a boil enhancing module.

### DETAILED DESCRIPTION

In the following embodiments, a term regarding “connection” or “communication” may refer to a physical connection or a direct connection or an indirect connection between physical elements, unless otherwise specified as an electrical connection or signal transmission. Moreover, the figures of the present invention are only illustrative, which are not necessarily drawn to scale, and all details are not necessarily presented in the figures.

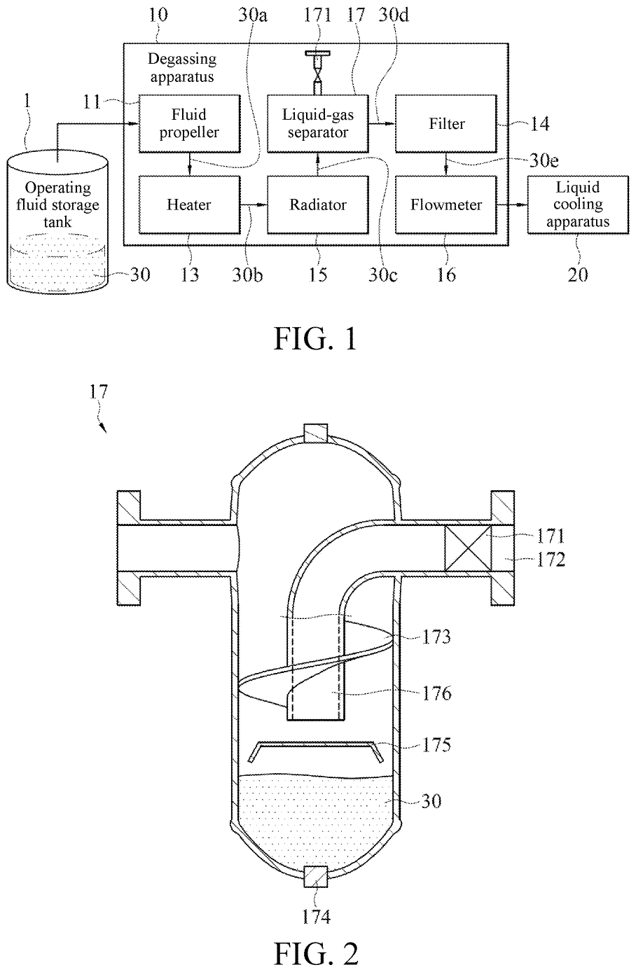

Refer to FIG. 1 and FIG. 2. FIG. 1 illustrates a schematic diagram (I) of a server cooling system according to some embodiments, with arrows indicating a flow direction of an operating fluid 30. FIG. 2 illustrates a schematic cross-sectional view of a liquid-gas separator 17 according to some embodiments, in which a spiral liquid guide plate 173 and a portion of a gas guide pipe member 176 are not sectioned.

Referring to FIG. 1, the server cooling system includes a liquid cooling apparatus 20 and a degassing apparatus 10. The degassing apparatus 10 includes a heater 13, a radiator 15, and a liquid-gas separator 17. The radiator 15 is in communication with the heater 13. The liquid-gas separator 17 is in communication with the radiator 15 and the liquid cooling apparatus 20. The liquid cooling apparatus 20 is suitable for dissipating heat from the server through the operating fluid 30. The liquid cooling apparatus 20 is for example but not limited to an immersion cooling apparatus or a rack-mounted cooling apparatus. The operating fluid 30 is for example but not limited to a non-conductive coolant. The non-conductive coolant includes, for example, non-conductive synthetic oil, a poly alpha olefin (PAO)-type coolant, a gas to liquid base oil (GTL)-type coolant, a synthetic ester type coolant, and a fluorocarbon coolant. In some embodiments, the operating fluid 30 may be a two-phase coolant.

The degassing apparatus 10 heats the operating fluid 30, causing air dissolved in the operating fluid 30 to be released due to an increase in a temperature of the operating fluid 30. Afterwards, the radiator 15 controls the heated operating fluid 30 at a specific temperature to maintain a specific proportion of released air in an undissolved state. Next, the liquid-gas separator 17 separates the released air from the degassed operating fluid 30. The released air is discharged, and the degassed operating fluid 30 is guided to the liquid cooling apparatus 20. In this way, a solubility of the operating fluid 30 in the liquid cooling apparatus 20 may be greatly reduced, thereby maintaining the air pressure of the liquid cooling apparatus 20.

Specifically, referring to FIG. 1, in some embodiments, a heater 13 of the degassing apparatus 10 is configured to heat the operating fluid 30 to output a heated fluid 30b. The heated fluid 30b has a first temperature, and the first temperature is higher than an operating temperature of the operating fluid 30. The heater 13 is, for example but not limited to an electric heater or a ceramic heater. In some embodiments, the operating temperature of the operating fluid 30 may be within a temperature range of a boiling point ±2 °C of the operating fluid 30. For example, if the boiling point of the operating fluid 30 is 49 °C, then the operating temperature of operating fluid 30 is in a range of 47 °C to 51 °C. A heating temperature set by heater 13 is higher than a minimum value of the operating temperature. In some embodiments, the first temperature is about 2 °C to 10 °C higher than the operating temperature. In some embodiments, the first temperature is the boiling point of the operating fluid 30.

The solubility (unit: air volume/liquid volume) of the operating fluid 30 may decrease as the temperature increases. A fluorine coolant is used as an example. At a room temperature such as 25 °C, the solubility of the operating fluid 30 is 30%. When the temperature rises above 49 °C, the solubility is less than 1%. When the heater 13 heats the temperature of the operating fluid 30 to a temperature higher than the operating temperature of the operating fluid 30 (for example, 49 °C) , the solubility of the operating fluid 30 may be reduced from the original 30% to less than 1%.

Referring to FIG. 1, the radiator 15 is configured to condense the heated fluid 30b to output a heat dissipation fluid 30c. The heat dissipation fluid 30c has a second temperature, and the second temperature is lower than the operating temperature. The radiator 15 is for example but not limited to a heat pipe radiator or a fin-tube radiator, for example, a liquid-gas heat exchange (L2A) hybrid heat dissipation module or a liquid-liquid heat exchange (L2L) heat dissipation module. In some embodiments, the second temperature is about 1 °C to 5 °C lower than the operating temperature. In some embodiments, the second temperature is 1 °C to 5 °C lower than the boiling point of the operating fluid 30. In some embodiments, the second temperature is not less than 45 °C. In some embodiments, a temperature of the heat dissipation fluid 30c is less than a temperature of the heated fluid 30b, and the temperature of the heat dissipation fluid 30c is still sufficient to cause the solubility of the operating fluid 30 to be less than a certain proportion (for example, a solubility is less than 10%).

The liquid-gas separator 17 is configured to perform liquid-gas separation on the heat dissipation fluid 30c, to respectively output a degassed fluid 30d and a gas. The liquid-gas separator 17 is for example but not limited to a gravity liquid-gas separator or a centrifugal liquid-gas separator. Referring to FIG. 2, in some embodiments, the liquid-gas separator 17 includes a spiral liquid guide plate 173, a gas check valve 171, a liquid separation baffle 175, and a gas guide pipe member 176. The spiral liquid guide plate 173 is arranged on an outer surface of the gas guide pipe member 176. An open end of the gas guide pipe member 176 is toward the liquid separation baffle 175 located at the bottom of a chamber of the liquid-gas separator 17, and another open end (that is, an upper outlet 172) is toward outside of the liquid-gas separator 17. The spiral liquid guide plate 173 is configured to cause the heat dissipation fluid 30c to generate a spiral centrifugal motion to separate the heat dissipation fluid 30c into the gas and the degassed fluid 30d. In addition, the gas guide pipe member 176 is provided with a gas check valve 171. The gas check valve 171 is close to the upper outlet 172, and the gas check valve 171 is configured to output a gas separated from the heat dissipation fluid 30c, so that the gas can only be discharged unidirectionally. The liquid separation baffle 175 is close to a lower outlet 174 of the spiral liquid guide plate 173, and the liquid separation baffle 175 is configured to separate the degassed fluid 30d from the gas. In some embodiments, the degassed fluid 30d may be an operating fluid 30 with a solubility reaching a preset value (for example, 1%), rather than a liquid without any gas dissolved therein.

Referring to FIG. 1, in some embodiments, the server cooling system further includes an operating fluid storage tank 1. The degassing apparatus 10 further includes a fluid propeller 11, a filter 14, and a flowmeter 16. The operating fluid storage tank 1 is configured to store the operating fluid 30. The fluid propeller 11 is in communication with the operating fluid storage tank 1. The fluid propeller 11 is configured to extract the operating fluid 30 from the operating fluid storage tank 1 to output a propelled fluid 30a. The fluid propeller 11 is for example but not limited to a pump or a circulation pump. The filter 14 is configured to filter impurities from the operating fluid 30. The filter 14 may be in communication with the liquid-gas separator 17 to filter the degassed fluid 30d and output a filtered fluid 30e. The filter 14 is for example but not limited to a filter, a filter pump, an oil-water separator, or a combination thereof. In addition, the flowmeter 16 is in communication with the filter 14 and the liquid cooling apparatus 20. The flowmeter 16 is configured to measure a flow rate of the operating fluid 30 filled into the liquid cooling apparatus 20, or measure a flow rate of the filtered fluid 30e.

FIG. 1 is used as an example. The fluid propeller 11 extracts the operating fluid 30 in the operating fluid storage tank 1 and outputs the propelled fluid 30a. The temperatures of the operating fluid 30 in the operating fluid storage tank 1 and the propelled fluid 30a are both 25 °C, and the solubility is about 30%. The heater 13 receives and heats the propelled fluid 30a to output the heated fluid 30b. After the heated fluid 30b is heated by the heater 13, the temperature of the heated fluid reaches 50 °C, and the solubility is reduced to below 1%. Since the purpose of the heater 13 is to boil the operating fluid 30, the heated fluid 30b is a mixture that may include a liquid operating fluid 30, a gaseous operating fluid 30, and air released due to a decrease in the solubility of the operating fluid 30 (hereinafter referred to as released air). The radiator 15 receives and condenses the heated fluid 30b and outputs the heat dissipation fluid 30c, where the temperature of the heat dissipation fluid 30c is about 49 °C. Since the purpose of the radiator 15 is to condense the operating fluid 30, the heat dissipation fluid 30c is a mixture that may include the liquid operating fluid 30 and the released air. Next, the heat dissipation fluid 30c flows into the liquid-gas separator 17 to be degassed.

Referring to FIG. 2, the heat dissipation fluid 30c flows along the spiral liquid guide plate 173. Under the action of centrifugal force, the liquid operating fluid 30 and the released air are separated. The released air is subjected to a relatively small gravity force, and then flows along the gas guide pipe member 176 and is discharged from the gas check valve 171 (the upper outlet 172). The liquid operating fluid 30 is subjected to a relatively large gravity force and flows out from the lower outlet 174. The liquid operating fluid 30 flowing out from the lower outlet 174 is a degassed fluid 30d, with a temperature of about 48 °C. The degassed fluid 30d is an operating fluid 30 with a solubility about in a range of 1% to 5%. The filter 14 filters the degassed fluid 30d and outputs the filtered fluid 30e. A temperature of the filtered fluid 30e is 47 °C, and a solubility thereof is about 5%. Finally, the filtered fluid 30e flows through the flowmeter 16 and then flows into the liquid cooling apparatus 20. This means that the operating fluid 30 entering a cooling circulation system of the liquid cooling apparatus 20 has a low solubility, and a gas volume required by the liquid cooling apparatus 20 may be reduced.

Some embodiments of the liquid cooling apparatus 20 being an immersion cooling apparatus are described in detail below.

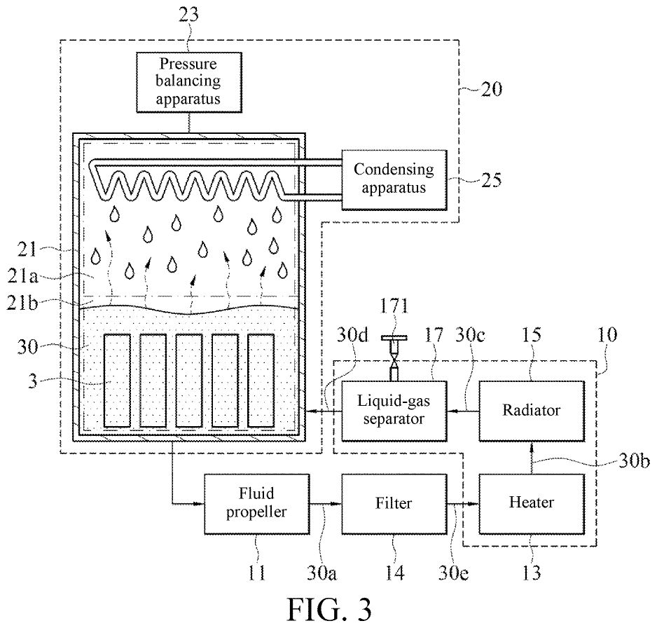

Refer to FIG. 3. FIG. 3 illustrates a schematic diagram (II) of a server cooling system according to some embodiments, with arrows indicating a flow direction of an operating fluid 30.

In some embodiments, a liquid cooling apparatus 20 is an immersion cooling apparatus, and the operating fluid 30 is a two-phase coolant. The liquid cooling apparatus 20 includes an immersion cooling tank 21, a condensing apparatus 25, and a pressure balancing apparatus 23. The immersion cooling tank 21 is configured to accommodate an operating fluid 30 and at least one electronic apparatus 3 (such as a server) partially immersed in the operating fluid 30. The immersion cooling tank 21 has a gas phase space 21a and a liquid phase space 21b. The gas phase space 21a is configured to accommodate a gaseous operating fluid 30, and the liquid phase space 21b is configured to accommodate a liquid operating fluid 30. The liquid phase space 21b is in communication with the degassing apparatus 10. The gas phase space 21a is in communication with the pressure balancing apparatus 23.

The pressure balancing apparatus 23 is configured to maintain a pressure of the immersion cooling tank 21 within a predetermined pressure range, for example, less than 1 atmospheric pressure. Specifically, the pressure balancing apparatus 23 may have an expandable and contractible space to accommodate gas from the gas phase space 21a. The pressure balancing apparatus 23 is for example but not limited to an air bellow or a bag structure (or referred to as a bellow) with expansion and contraction functions. Accordingly, the pressure balancing apparatus 23 may adjust an internal pressure of the immersion cooling tank 21 by changing a volume of the expandable and contractible space. For example, the internal pressure is maintained in a negative pressure state less than or equal to the external pressure (for example, 1 atmospheric pressure). Specifically, if the operating fluid 30 entering the immersion cooling tank 21 is heated without being properly degassed, the operating fluid 30 may be caused to vaporize due to heating and release air inside the liquid, so that the pressure in the immersion cooling tank 21 increases accordingly, causing the gas in the gas phase space 21a to flow into the pressure balancing apparatus 23. To maintain the negative pressure state, the immersion cooling tank 21 may be configured with a plurality of pressure balancing apparatuses 23. In some embodiments, the pressure balancing apparatus 23 may further have a driving element. The driving element is for example but not limited to a motor or an air cylinder. The driving element is configured to drive the gas in the gas phase space 21a to flow toward the expandable and contractible space.

The condensing apparatus 25 may include a water cooling pipe member, a water pump, and a water chiller unit. A portion of the water cooling pipe member is located in the gas phase space 21a of the immersion cooling tank 21, and another portion of the water cooling pipe member is arranged on an outer side of the immersion cooling tank 21 and connected to the water pump and the water chiller unit. For example, the coolant inside the water cooling pipe member located in the gas phase space 21a absorbs the heat of the gaseous operating fluid 30, and the heated coolant in the water cooling pipe member is pushed by the water pump to the water chiller unit for heat dissipation and cooling. Next, the cooled coolant flows back into the gas phase space 21a of the immersion cooling tank 21 for next heat dissipation circulation. On the other hand, the gaseous operating fluid 30 is condensed into a liquid state due to the heat dissipation effect of the water cooling pipe member, and flows back to the liquid phase space 21b of the immersion cooling tank 21.

Referring to FIG. 3, the degassing apparatus 10 may further include a fluid propeller 11 and a filter 14. The liquid phase space 21b of the immersion cooling tank 21 is in communication with the fluid propeller 11 and the liquid-gas separator 17. The fluid propeller 11 is configured to extract the liquid operating fluid 30 in the immersion cooling tank 21 to output a propelled fluid 30a. The liquid-gas separator 17 is configured to output the degassed fluid 30d to the immersion cooling tank 21.

Specifically, FIG. 3 is used as an example. The liquid operating fluid 30 in the immersion cooling tank 21 absorbs heat of the server and vaporizes, and releases air in the liquid. Part of the gas in the gas phase space 21a is allowed to flow to the pressure balancing apparatus 23, so that the internal pressure of the immersion cooling tank 21 may be adjusted (for example, maintained in a negative pressure state). In this case, the temperature of the liquid operating fluid 30 in the liquid phase space 21b is about 47 °C. The fluid propeller 11 extracts the liquid operating fluid 30 in the immersion cooling tank 21 and outputs the propelled fluid 30a. The filter 14 filters the propelled fluid 30a and outputs a filtered fluid 30e. The heater 13 receives the filtered fluid 30e and outputs a heated fluid 30b. A temperature of the heated fluid 30b is for example 55 °C. The heated fluid 30b is mainly a gaseous operating fluid 30 and releases air. In an embodiment of the figure, since the filter 14 is located upstream of the heater 13, the operating fluid 30 flows through the filter 14 in advance, which may save energy consumption of the downstream heater 13. In other words, the heater 13 only needs to heat the operating fluid 30 from the temperature of 47 °C to 55 °C. Next, the heated fluid 30b is condensed through the radiator 15 to become a heat dissipation fluid 30c of 48 °C. The heat dissipation fluid 30c is mainly a liquid operating fluid 30 and releases air. The liquid-gas separator 17 receives the heat dissipation fluid 30c and separates the liquid operating fluid 30 (that is, the degassed fluid 30d) from the released air. The gas check valve 171 outputs the released air. The degassed fluid 30d flows back to the immersion cooling tank 21. The temperature of the degassed fluid 30d is for example 48 °C.

In some embodiments, a total volume of the gas phase space 21a and the liquid phase space 21b is a first volume. The pressure balancing apparatus 23 has a gas-containing volume. The gas-containing volume is 1% to 30% of the first volume. The gas-containing volume may be the maximum volume of the expandable and contractible space of the pressure balancing apparatus 23.

For example, referring to FIG. 3, a large amount of liquid operating fluid 30 (such as 300 liters) is often filled into the immersion cooling tank 21 of the immersion cooling apparatus. A ratio of a volume of the gas phase space 21a to a volume of the liquid phase space 21b is about 3:7. If the operating fluid 30 at 25 °C is filled and has a solubility up to 30%, the gas-containing volume of the pressure balancing apparatus 23 needs to reach 90 liters to maintain the negative pressure state of the immersion cooling tank 21. If the operating fluid 30 is first heated and degassed by the degassing apparatus 10 before being filled into the liquid cooling apparatus 20, the solubility is reduced to 10%, and then the gas-containing volume of the pressure balancing apparatus 23 configured for the liquid cooling apparatus 20 only needs to reach 9 liters. Therefore, the gas-containing volume of the pressure balancing apparatus 23 may be greatly reduced.

In this way, since the degassing apparatus 10 may maintain the solubility of the operating fluid 30 to a certain extent, thereby reducing an amount of air released by the operating fluid 30 due to heat absorption, the internal pressure of the immersion cooling tank 21 may be stably maintained.

In some embodiments, the immersion cooling tank 21 is in direct communication with the heater 13, and the filter 14 is mounted between the liquid-gas separator 17 and the immersion cooling tank 21. The degassed fluid 30d outputted from the liquid-gas separator 17 is filtered by the filter 14 before flowing into the immersion cooling tank 21.

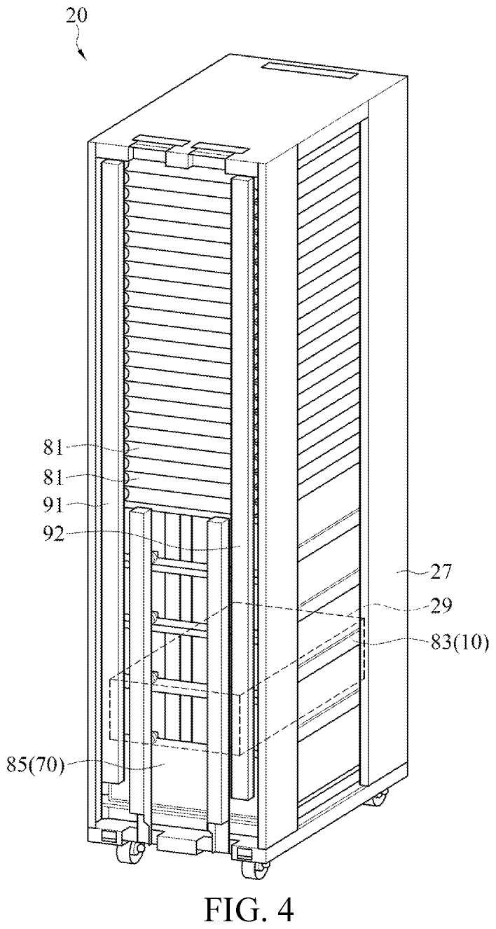

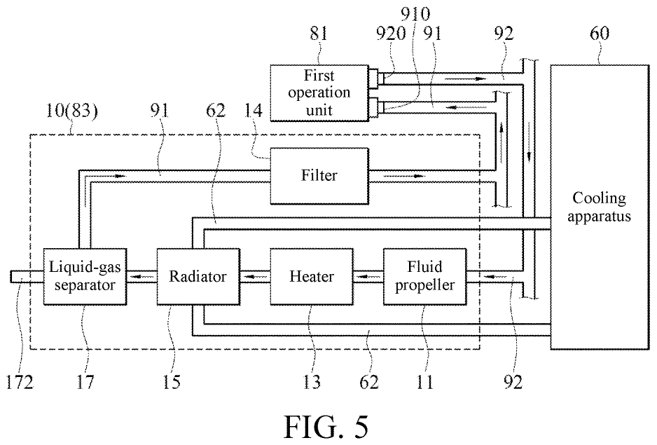

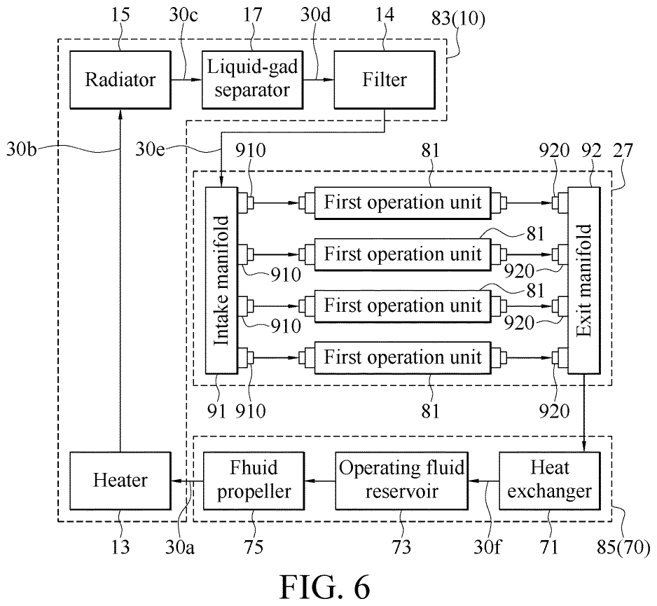

Refer to FIG. 4, FIG. 5, and FIG. 6. FIG. 4 illustrates a schematic diagram (III) of a server cooling system according to some embodiments, showing that a first operation unit 81, a second operation unit 83, and a third operation unit 85 are configured in a same server rack 27. FIG. 5 illustrates a schematic diagram (IV) of a server cooling system according to some embodiments, showing a connection relationship between a first operation unit 81 and a degassing apparatus 10, with arrows indicating a flow direction of an operating fluid 30. FIG. 6 illustrates a schematic diagram (V) of a server cooling system according to some embodiments, showing a connection relationship between a first operation unit 81, a second operation unit 83, and a third operation unit 85, with arrows indicating a flow direction of an operating fluid 30.

Referring to FIG. 4 and FIG. 6, in some embodiments, the server cooling system further includes an operating fluid distribution unit (cooling distribution unit, CDU) 70 configured to accommodate and distribute the operating fluid 30 to a server, an operation unit, or another device. Some embodiments of the liquid cooling apparatus 20 being a rack-mounted server cooling apparatus are described in detail below.

Referring to FIG. 4, in some embodiments, the liquid cooling apparatus 20 is a rack-mounted server cooling apparatus and is configured with a plurality of operation units. The operating fluid 30 circulates in the operation units. Each operation unit has a standardized chassis 29, for example, 1U, 2U, 3U, or 4U. In some embodiments, a width of the chassis 29 of an operation unit is 19 inches or 23 inches, and a height of the chassis 29 is a positive integer multiple of 1.75 inches.

In some embodiments, the degassing apparatus 10, the operating fluid distribution unit 70, and the server are all modular and detachable from the operation unit of the server rack 27. Specifically, referring to FIG. 4, the operation units include the first operation unit 81, the second operation unit 83, and the third operation unit 85. A quantity of first operation units 81, a quantity of second operation units 83, and a quantity of third operation units 85 may be each single or plural.

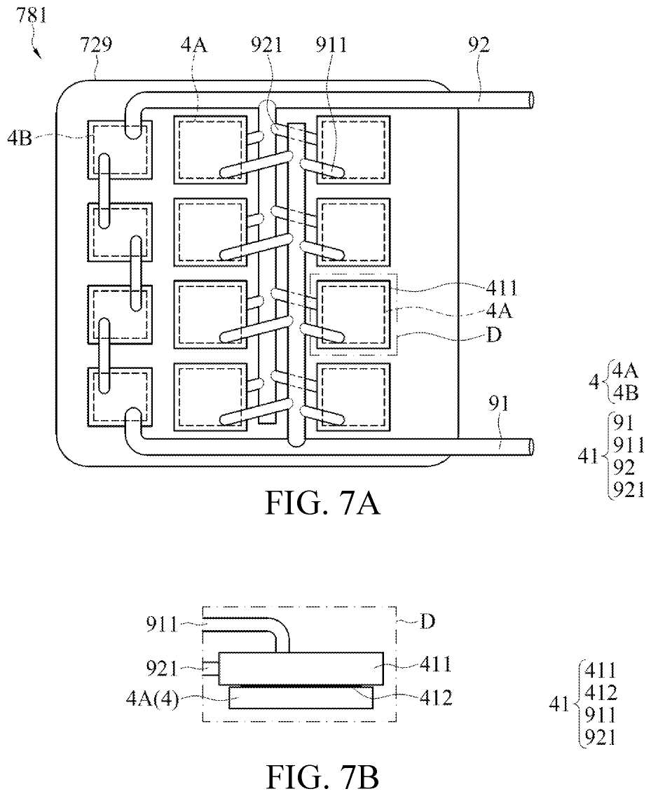

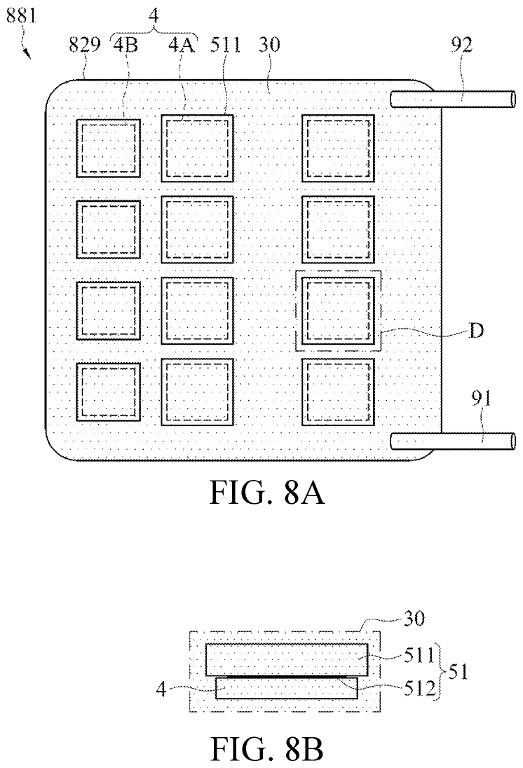

Refer to FIG. 7A to FIG. 8B. FIG. 7A illustrates a schematic structural diagram of a first operation unit 781 according to some embodiments, showing that a liquid cooling apparatus 20 further includes a cold plate module 41, and a plurality of to-be-cooled elements 4 are configured inside a chassis 729. FIG. 7B illustrates a partial enlarged view of an area D marked in FIG. 7A and viewed from the bottom to top of a perspective of FIG. 7A in the area D, showing a connection relationship between a to-be-cooled element 4, a cold plate 411, an intake manifold branch 911, and an exit manifold branch 921. FIG. 8A illustrates a schematic top view of a first operation unit 81 according to some other embodiments, showing that a chassis 829 of the first operation unit 881 is a sealed chassis to accommodate an operating fluid 30, a boiler 511, and a to-be-cooled element 4. FIG. 8B illustrates a partial enlarged view of an area D marked in FIG. 8A and viewed from the bottom to top of a perspective of FIG. 8A in the area D, showing a to-be-cooled element 4 and a boil enhancing module 51.

Referring to FIG. 7A and FIG. 7B, the first operation unit 781 may be a server module arranged in a rack. The chassis 729 of the first operation unit 781 may accommodate at least one to-be-cooled element 4. The to-be-cooled element 4 is for example but not limited to a processor 4A (CPU or GPU) or a switch 4B (for example, a network switch). In some embodiments, the liquid cooling apparatus 20 further includes a cold plate module 41 configured to dissipate heat from the to-be-cooled element 4. The cold plate module 41 includes, for example, but not limited to, an operating fluid inlet, at least one cold plate 411 thermally coupled to at least one to-be-cooled element 4, an operating fluid flow channel (for example, an intake manifold 91, an intake manifold branch 911, an exit manifold 92, an exit manifold branch 921), and a thermal interface material (TIM) 412. The cold plate 411 is in communication with the intake manifold branch 911 and the intake manifold 91, and is brought into communication with the exit manifold 92 through the exit manifold branch 921. The TIM 412 is configured to bond the cold plate 411 and the to-be-cooled element 4, and includes a thermally conductive paste and/or a thermally conductive pad. For example, the fluid propeller 11 of the degassing apparatus 10 in FIG. 5 extracts the operating fluid 30 from the cold plate 411 in FIG. 7B to output a propelled fluid. The heater 13 heats the propelled fluid to output a heated fluid. Next, the heated fluid flows through the radiator 15 and the liquid-gas separator 17 in sequence, and the liquid-gas separator 17 outputs a degassed fluid. A filter 14 filters the degassed fluid to output a filtered fluid to the cold plate 411 in FIG. 7B. Accordingly, the degassed operating fluid 30 enters the cold plate 411 through the intake manifold 91 and the intake manifold branch 911, exchanges heat with the to-be-cooled element 4, and then flows out from the first operation unit 781 through the exit manifold branch 921 and the exit manifold 92. In some embodiments, the chassis 729 may be non-sealed. In other words, the chassis 729 may further be configured with an air cooling element such as a fan. In some embodiments, the chassis 729 may further be configured with another temperature equalization apparatus such as a heat pipe, to enhance a cooling effect.

4 cold plates 411 corresponding to 4 switches 4B on a left side of FIG. 7A are in communication with pipe members (the intake manifold 91 and the exit manifold 92) in series. The operating fluid 30 flows into the cold plate 411 configured on the switch 4B through the intake manifold 91, passes through all the cold plates 411 located downstream of the switch 4B in sequence along the pipe members, and then flows out from the chassis 729 through the exit manifold 92. On the other hand, 8 cold plates 411 corresponding to the 8 processors 4A in FIG. 7A are in communication with the pipe members (the intake manifold 91 and the exit manifold 92) in parallel. The filtered fluid 30e flowing out from the filter 14 (see FIG. 6) flows into the intake manifold 91, is shunted to each cold plate 411 arranged on the processor 4A, then flows through the corresponding exit manifold branch 921 to converges to the exit manifold 92, and then flows out from the chassis 729. In some embodiments, a connection manner between a plurality of cold plates 411 may be adjusted as needed.

Referring to FIG. 8A and FIG. 8B, in some embodiments, the chassis 829 of the first operation unit 881 is a sealed chassis to accommodate the operating fluid 30 and a to-be-cooled element 4 at least partially immersed in the operating fluid 30, and the sealed chassis may prevent the gaseous operating fluid 30 from escaping. The operating fluid 30 in the chassis 829 is configured to exchange heat with the to-be-cooled element 4 (for example, a processor 4A or a switch 4B). In such an embodiment, the first operation unit 881 adopts an immersion cooling manner, and a boil enhancing module 51 may be arranged on the to-be-cooled element 4. The liquid cooling apparatus 20 further includes a boil enhancing module 51. The boil enhancing module 51 is configured to be thermally coupled to the to-be-cooled element 4. The boil enhancing module 51 includes, but is not limited to, a boiler 511 and a TIM 512. For example, the fluid propeller 11 of the degassing apparatus 10 in FIG. 5 extracts the operating fluid 30 in the sealed chassis of the first operation unit 881 in FIG. 8A to output a propelled fluid. The heater 13 heats the propelled fluid to output a heated fluid. Next, the heated fluid flows through the radiator 15 and the liquid-gas separator 17 in sequence, and the liquid-gas separator 17 outputs a degassed fluid. The filter 14 filters the degassed fluid to output a filtered fluid to the chassis 829 in FIG. 8A. Accordingly, the degassed operating fluid 30 flows into the chassis 829 through the intake manifold 91, and part of the operating fluid 30 evaporates into gas due to heat exchange with the boil enhancing module 51. Next, the operating fluid 30 (including a gas state, a liquid state, or a liquid-gas coexisting state) that has undergone heat exchange flows out from the chassis 829 through the exit manifold 92.

The second operation unit 83 is a general term for the degassing apparatus 10. FIG. 6 is used as an example. The degassing apparatus 10 includes a heater 13, a radiator 15, a liquid-gas separator 17, and a filter 14. The heater 13, the radiator 15, the liquid-gas separator 17, and the filter 14 are all accommodated in the chassis 29 of the second operation unit 83 (see FIG. 4).

The third operation unit 85 is a general term for the operating fluid distribution unit 70. Referring to FIG. 4, the first operation unit 81 is arranged on the top of the server rack 27, the third operation unit 85 (the operating fluid distribution unit 70) is arranged on the bottom of the server rack 27, and the second operation unit 83 (the degassing apparatus 10) is close to the third operation unit 85.

Referring to FIG. 4 and FIG. 6, the server rack 27 includes an intake manifold 91 and an exit manifold 92. The intake manifold 91 has a manifold inlet 910. The exit manifold 92 has a manifold outlet 920. The first operation unit 81, the second operation unit 83, and the third operation unit 85 are in communication with each other through the intake manifold 91 and the exit manifold 92. For example, referring to FIG. 6, the operating fluid 30 in the first operation unit 81 absorbs heat and flows to the third operation unit 85 (the operating fluid distribution unit 70) along the exit manifold 92. Due to vaporization of the operating fluid 30 by absorbing heat generated by the server, the operating fluid 30 flowing out from the first operation unit 81 is mainly a gaseous operating fluid 30 with a temperature of for example 50 °C. The operating fluid distribution unit 70 is in communication with the manifold outlet 920 and configured to accommodate and output the operating fluid 30. The operating fluid distribution unit 70 may include a heat exchanger 71, an operating fluid reservoir 73, and a fluid propeller 75. The heat exchanger 71 is in communication with the first operation unit 81. The operating fluid reservoir 73 is in communication with the heat exchanger 71. The fluid propeller 75 is in communication with the operating fluid reservoir 73 and the degassing apparatus 10. Specifically, the heat exchanger 71 receives the gaseous operating fluid 30 and performs heat exchange to output a to-be-degassed fluid 30f. The to-be-degassed fluid 30f is mainly a liquid operating fluid 30, and a temperature of the to-be-degassed fluid 30f is for example 47 °C. The operating fluid reservoir 73 receives and accommodates the to-be-degassed fluid 30f. The fluid propeller 75 extracts the to-be-degassed fluid 30f from the operating fluid reservoir 73 and propels the to-be-degassed fluid to the heater 13.

Next, the heater 13 of the degassing apparatus 10 heats the temperature of the operating fluid 30 outputted from the operating fluid distribution unit 70 to for example 50 °C The radiator 15 condenses the heated fluid 30b from the heater 13. An output of the radiator 15 is for example a heat dissipation fluid 30c at a temperature of 49 °C. The heat dissipation fluid 30c is separated by the liquid-gas separator 17, and a released gas is discharged. The degassed fluid 30d is filtered by the filter 14 into a filtered fluid 30e. Finally, the filtered fluid 30e flows back from the manifold inlet 910 to the first operation unit 81 along the intake manifold 91. In this way, since the filter 14 is arranged upstream of the first operation unit 81, the operating fluid 30 may be filtered before flowing into microstructures such as the cold plate and the operating fluid flow channel of the first operation unit 81. In addition, the filter 14 is arranged in the chassis 29, which provides convenience for maintenance.

In some embodiments, the liquid cooling apparatus 20 is externally connected to the operating fluid distribution unit 70. For example, the server rack 27 of the liquid cooling apparatus 20 in FIG. 4 is only provided with the first operation unit 81 and the second operation unit 83, and the operating fluid distribution unit 70 is arranged on another independent rack in communication with the liquid cooling apparatus 20. The heat exchanger 71 of the operating fluid distribution unit 70 is in communication with the first operation unit 81. The fluid propeller 75 of the operating fluid distribution unit 70 is in communication with the heater 13 of the second operation unit 83. The structural details of this embodiment are similar to those of the above embodiments, and details are not described again.

Referring to FIG. 6, in some embodiments, the operating fluid distribution unit 70 may include a heat exchanger 71, an operating fluid reservoir 73, a fluid propeller 75, a heater 13, a radiator 15, a liquid-gas separator 17, and a filter 14. In this embodiment, the operating fluid distribution unit 70 has functions of degassing and distributing the operating fluid 30. The operating fluid distribution unit 70 and the liquid cooling apparatus 20 may be externally connected, or the operating fluid distribution unit 70 may be mounted as a modular operation unit in the server rack 27 of the liquid cooling apparatus 20.

For example, the heat exchanger 71, the operating fluid reservoir 73, the fluid propeller 75, the heater 13, the radiator 15, the liquid-gas separator 17, and the filter 14 are all accommodated in the chassis 29 of the third operation unit 85 in FIG. 4. The heat exchanger 71 of the operating fluid distribution unit 70 is in communication with the first operation unit 81. In the operating fluid distribution unit 70, the operating fluid 30 flows through the heat exchanger 71, the operating fluid reservoir 73, the fluid propeller 75, the heater 13, the radiator 15, the liquid-gas separator 17, and the filter 14 in sequence. The structural details are similar to those of the previous embodiments, and details are not described again. Therefore, the operating fluid 30 is heated and degassed before being distributed to a different first operation unit to absorb the heat of the server. The operating fluid 30 flowing out from the first operation unit 81 may flow back to the operating fluid distribution unit 70 for heat dissipation, degassing, and filtration, and then enters a next cooling cycle.

Referring to FIG. 4 and FIG. 5, in some embodiments, the server rack 27 is only provided with the first operation unit 81, and the degassing apparatus 10 is arranged in another independent rack in communication with the liquid cooling apparatus 20. The degassing apparatus 10 includes a fluid propeller 11, a heater 13, a radiator 15, a liquid-gas separator 17, and a filter 14. The radiator 15 is in communication with a cooling apparatus 60. The cooling apparatus 60 is configured to provide cooling water for the radiator 15 to dissipate heat from the operating fluid 30. The cooling apparatus 60 includes, but not limited to, a water cooling pipe member 62, a water pump, and a water cooling tower. The cooling water circulates between the cooling apparatus 60 and the radiator 15 along the water cooling pipe member 62.

For example, referring to FIG. 5, the operating fluid 30 in the first operation unit 81 absorbs heat and flows into the degassing apparatus 10 along the exit manifold 92. In the degassing apparatus 10, the operating fluid 30 flows through the fluid propeller 11, the heater 13, the radiator 15, the liquid-gas separator 17, and the filter 14 in sequence. Finally, the operating fluid 30 flowing out from the filter 14 flows back to the first operation unit 81 along the intake manifold 91. A temperature of the operating fluid 30 flowing into the first operation unit 81 is controlled at a preset temperature (for example, 45 °C). Therefore, a solubility of the operating fluid 30 may be maintained at a certain level.

Referring to FIG. 6, in some embodiments, the server rack 27 of the liquid cooling apparatus 20 is provided with first operation units 81 and a third operation unit 85. The degassing apparatus 10 is arranged in another independent rack in communication with the liquid cooling apparatus 20 in FIG. 4. The heater 13 of the degassing apparatus 10 is in communication with a fluid propeller 75 of the third operation unit 85. In the degassing apparatus 10, the operating fluid 30 flows through the heater 13, the radiator 15, the liquid-gas separator 17, and the filter 14 in sequence. Finally, the operating fluid 30 flowing out from the filter 14 flows back to the first operation unit 81 along the intake manifold 91.

Based on the above, according to some embodiments, the operating fluid 30 is first degassed before being filled into the liquid cooling apparatus 20, so that the air pressure in the chassis 29 or an immersion tank may be maintained, thereby reducing a degree of fluid leakage. According to some embodiments, the risk of hardware damage due to gas expansion caused by heat exchange may also be reduced.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A server cooling system, comprising:
a liquid cooling apparatus; and
a degassing apparatus, comprising:
a heater;
a radiator, in communication with the heater; and
a liquid-gas separator, in communication with the radiator and the liquid cooling apparatus.

2. The server cooling system according to claim 1, wherein
the heater is configured to heat an operating fluid to output a heated fluid, the heated fluid has a first temperature, and the first temperature is higher than an operating temperature of the operating fluid;
the radiator is configured to condense the heated fluid to output a heat dissipation fluid, the heat dissipation fluid has a second temperature, and the second temperature is lower than the operating temperature; and
the liquid-gas separator is configured to perform liquid-gas separation on the heat dissipation fluid to respectively output a degassed fluid and a gas, and the liquid-gas separator outputs the degassed fluid to the liquid cooling apparatus.

3. The server cooling system according to claim 2, wherein the first temperature is about 2 °C to 10 °C higher than the operating temperature, and the second temperature is about 1 °C to 5 °C lower than the operating temperature.

4. The server cooling system according to claim 2, wherein the liquid-gas separator comprises:
a spiral liquid guide plate, configured to cause the heat dissipation fluid to generate a spiral centrifugal motion to separate the heat dissipation fluid into the gas and the degassed fluid;
a gas check valve, configured to output the gas separated from the heat dissipation fluid; and
a liquid separation baffle, configured to separate the degassed fluid from the gas.

5. The server cooling system according to claim 2, wherein the liquid cooling apparatus is configured with a plurality of operation units, each of the operation units has a chassis, and the chassis is configured to accommodate at least one to-be-cooled element; the liquid cooling apparatus further comprises at least one cold plate, and the at least one cold plate is configured to be thermally coupled to the at least one to-be-cooled element;
the degassing apparatus further comprises a fluid propeller and a filter, the fluid propeller extracts the operating fluid in the at least one cold plate to output a propelled fluid, the heater heats the propelled fluid to output the heated fluid, and the filter filters the degassed fluid to output a filtered fluid to the at least one cold plate.

6. The server cooling system according to claim 2, wherein the liquid cooling apparatus is configured with a plurality of operation units, each of the operation units has a sealed chassis, the sealed chassis is configured to accommodate at least one to-be-cooled element, the liquid cooling apparatus further comprises at least one boil enhancing module, and the at least one boil enhancing module is configured to be thermally coupled to the at least one to-be-cooled element;
the degassing apparatus further comprises a fluid propeller and a filter, the fluid propeller extracts the operating fluid in the sealed chassis of each operation unit to output a propelled fluid, the heater heats the propelled fluid to output the heated fluid, and the filter filters the degassed fluid to output a filtered fluid to the sealed chassis.

7. The server cooling system according to claim 1, wherein the liquid cooling apparatus comprises:
an immersion cooling tank, configured to accommodate an operating fluid and at least one electronic apparatus partially immersed in the operating fluid, wherein the immersion cooling tank has a liquid phase space and a gas phase space, and the liquid phase space is in communication with the liquid-gas separator; and
a pressure balancing apparatus, in communication with the gas phase space and configured to maintain a pressure of the immersion cooling tank within a predetermined pressure range.

8. The server cooling system according to claim 7, wherein a total volume of the gas phase space and the liquid phase space is a first volume, the pressure balancing apparatus has a gas-containing volume, and the gas-containing volume is 1% to 30% of the first volume.

9. The server cooling system according to claim 7, further comprising:
a fluid propeller, configured to extract the operating fluid in the immersion cooling tank to output a propelled fluid; and
a filter, configured to filter the propelled fluid to output a filtered fluid, wherein the heater receives and heats the filtered fluid to output a heated fluid, the heated fluid has a first temperature, the first temperature is higher than an operating temperature of the operating fluid, the radiator condenses the heated fluid to output a heat dissipation fluid, the liquid-gas separator performs liquid-gas separation on the heat dissipation fluid to respectively output a degassed fluid and a gas, and the liquid-gas separator outputs the degassed fluid to the immersion cooling tank.

10. The server cooling system according to claim 1, further comprising an operating fluid storage tank, wherein the degassing apparatus further comprises:
a fluid propeller, in communication with the operating fluid storage tank; and
a filter, in communication with the liquid-gas separator.

11. The server cooling system according to claim 10, wherein the operating fluid storage tank is configured to store an operating fluid;
the fluid propeller is configured to extract the operating fluid from the operating fluid storage tank to output a propelled fluid;
the heater receives and heats the propelled fluid to output a heated fluid, the heated fluid has a first temperature, and the first temperature is higher than an operating temperature of the operating fluid;
the radiator condenses the heated fluid to output a heat dissipation fluid, the heat dissipation fluid has a second temperature, and the second temperature is lower than the operating temperature;
the liquid-gas separator performs liquid-gas separation on the heat dissipation fluid to respectively output a degassed fluid and a gas; and
the filter is configured to filter the degassed fluid and output a filtered fluid to the liquid cooling apparatus.

12. The server cooling system according to claim 1, further comprising an operating fluid distribution unit, and the operating fluid distribution unit comprises:
a heat exchanger, in communication with the liquid cooling apparatus;
an operating fluid reservoir, in communication with the heat exchanger; and
a fluid propeller, in communication with the operating fluid reservoir and the heater.

13. The server cooling system according to claim 12, further comprising a server rack, wherein the server rack comprises an intake manifold and an exit manifold, the intake manifold has a manifold inlet, and the exit manifold has a manifold outlet, wherein
the operating fluid distribution unit is in communication with the manifold outlet, and the operating fluid distribution unit is configured to accommodate and output an operating fluid;
the heater is configured to heat the operating fluid outputted from the operating fluid distribution unit to output a heated fluid, the heated fluid has a first temperature, and the first temperature is higher than an operating temperature of the operating fluid;
the radiator is configured to condense the heated fluid to output a heat dissipation fluid, the heat dissipation fluid has a second temperature, and the second temperature is lower than the operating temperature; and
the liquid-gas separator is configured to perform liquid-gas separation on the heat dissipation fluid to respectively output a degassed fluid and a gas, and the liquid-gas separator outputs the degassed fluid to the manifold inlet.

14. The server cooling system according to claim 13, wherein the heat exchanger performs heat exchange on the operating fluid outputted from the server rack, and outputs a to-be-degassed fluid to the operating fluid reservoir; and
the fluid propeller extracts the to-be-degassed fluid from the operating fluid reservoir to output a propelled fluid, wherein the heater heats the propelled fluid to output the heated fluid.

15. The server cooling system according to claim 14, wherein the degassing apparatus further comprises:
a filter, configured to filter the degassed fluid to output a filtered fluid to the manifold inlet.

16. The server cooling system according to claim 13, wherein the degassing apparatus has a chassis, wherein a width of the chassis is 19 inches or 23 inches, and a height of the chassis is a positive integer multiple of 1.75 inches, and the chassis is configured in the server rack.

17. An operating fluid distribution unit, comprising:
a heat exchanger;
an operating fluid reservoir, in communication with the heat exchanger;
a fluid propeller, in communication with the operating fluid reservoir;
a heater, in communication with the fluid propeller;
a radiator, in communication with the heater;
a liquid-gas separator, in communication with the radiator; and
a filter, in communication with the liquid-gas separator.

18. The operating fluid distribution unit according to claim 17, wherein
the heat exchanger is configured to perform heat exchange on an operating fluid to output a to-be-degassed fluid;
the operating fluid reservoir is configured to store the to-be-degassed fluid;
the fluid propeller is configured to extract the to-be-degassed fluid from the operating fluid reservoir, to output a propelled fluid;
the heater is configured to heat the propelled fluid to output a heated fluid, the heated fluid has a first temperature, and the first temperature is higher than an operating temperature of the operating fluid;
the radiator is configured to condense the heated fluid to output a heat dissipation fluid, the heat dissipation fluid has a second temperature, and the second temperature is lower than the operating temperature; and
the liquid-gas separator is configured to perform liquid-gas separation on the heat dissipation fluid to respectively output a degassed fluid and a gas, and the liquid-gas separator outputs the degassed fluid to a liquid cooling apparatus.

19. The operating fluid distribution unit according to claim 18, wherein the liquid-gas separator comprises:
a spiral liquid guide plate, configured to cause the heat dissipation fluid to generate a spiral centrifugal motion to separate the heat dissipation fluid into the gas and the degassed fluid;
a gas check valve, configured to output the gas separated from the heat dissipation fluid; and
a liquid separation baffle, configured to separate the degassed fluid from the gas.

20. The operating fluid distribution unit according to claim 17, further comprising a chassis, wherein the heat exchanger, the operating fluid reservoir, the fluid propeller, the heater, the radiator, the liquid-gas separator, and the filter are accommodated in the chassis, a width of the chassis is 19 inches or 23 inches, and a height of the chassis is a positive integer multiple of 1.75 inches.

21. A degassing apparatus, comprising:
a heater, configured to heat an operating fluid to output a heated fluid, wherein the heated fluid has a first temperature, and the first temperature is higher than an operating temperature of the operating fluid;
a radiator, configured to condense the heated fluid to output a heat dissipation fluid, wherein the heat dissipation fluid has a second temperature, and the second temperature is lower than the operating temperature; and
a liquid-gas separator, configured to perform liquid-gas separation on the heat dissipation fluid to respectively output a degassed fluid and a gas.

22. The degassing apparatus according to claim 21, further comprising:
a fluid propeller, configured to propel the operating fluid to the heater.

23. The degassing apparatus according to claim 22, further comprising:
a filter, configured to filter a propelled fluid outputted from the fluid propeller and output a filtered fluid, wherein the heater heats the filtered fluid to output the heated fluid.

24. The degassing apparatus according to claim 21, further comprising:
a filter, configured to filter the degassed fluid and output a filtered degassed fluid.

25. The degassing apparatus according to claim 21, further comprising:
a chassis, wherein the heater, the radiator, and the liquid-gas separator are accommodated in the chassis, a width of the chassis is 19 inches or 23 inches, and a height of the chassis is a positive integer multiple of 1.75 inches.

26. The degassing apparatus according to claim 21, wherein the liquid-gas separator comprises:
a spiral liquid guide plate, configured to cause the heat dissipation fluid to generate a spiral centrifugal motion to separate the heat dissipation fluid into the gas and the degassed fluid;
a gas check valve, configured to output the gas separated from the heat dissipation fluid; and
a liquid separation baffle, configured to separate the degassed fluid from the gas.
